(19) United States
(12) Patent Application Publication
(10) Pub. No.: US 2004/0241906 A1
(43) Pub. Date: Dec. 2, 2004

(54) Integrated circuit package and method for making same that employs under bump metalization layer

(76) Inventor: Vincent Chan, Richmond Hill (CA)

Correspondence Address: Christopher J. Reckamp, Vedder, Price, Kaufman & Kammholz, 222 North LaSalle Street, Chicago, IL, 60601, US

(21) Appl. No.: 10/446,997

(22) Filed: May 28, 2003

(51) Int. Cl. H01L 21/44; H01L 21/48; H01L 21/50

(52) U.S. Cl. 438/107

(57) ABSTRACT

An integrated circuit packaging method includes applying an under bump metalization (UBM) layer over an electrical contact pad surface, and any intervening layers, of an integrated circuit die, and applying, such as by soldering, a surface mount component directly to the integrated circuit die by applying the surface mount component to the UBM layer. This provides a direct electrical and mechanical coupling of the surface mount component to the integrated circuit die since the surface mount component is directly electrically connected with the electrical contact pad of the integrated circuit die. As such, impedance may be reduced and the coefficient of thermal mismatch between silicon integrated dies and the surface mount component may be minimized.

### FIELD OF THE INVENTION

The invention relates generally to integrated circuit packages and methods for making the same, and more particularly to integrated circuit packages and methods for making the same that employ under bump metalization layers.

### BACKGROUND OF THE INVENTION

Integrated circuit packages, such as semiconductor packages, may include an integrated circuit die mounted to a substrate material which may in turn be packaged inside a surface mount and capsulated package. Integrated circuits that require the use of passive components such as capacitors, resistors, or other passive components may employ surface mount components.

Typically, the surface mount components are assembled in the package to reduce power and ground noise. These surface mount components, such as surface mount capacitors, are normally connected to power and ground connections of the silicon die through bonding wires and traces on the package substrate material. The impedance of these connections can reduce the effectiveness of the decoupling capacitors to reduce power and ground noise. Accordingly, it would be desirable to have an integrated circuit package and method that improved upon the wire bonding of surface mount passive components to integrated circuit dies.

It is also generally known to use flip chip processes that use under bump metalization layers to mount integrated circuit dies to printed circuit boards. For example, it is known to use under bump metalization layers on top of aluminum or copper bonding pads to provide a stress buffer between an integrated circuit die and solder that is placed on the pad. However, integrated circuit packages that employ such methods still typically connect surface mount components to an integrated circuit die through a wire bonding process.

Accordingly, a need exists for an improved integrated circuit package and method that does not require the use of a wire bonding operation to connect surface mount components to integrated circuit die within an integrated circuit package.

### BRIEF DESCRIPTION OF THE DRAWINGS

FIG. 1 diagrammatically illustrates a wafer that contains a plurality of integrated circuit dies, each having a plurality of electrical contact pad surfaces thereon;

FIG. 2 is a diagram illustrating a top view of an integrated circuit die having affixed thereon a surface mount component that is applied directly to a plurality of contact pad surfaces in accordance with one embodiment of the invention;

FIG. 3 is a flow chart illustrating a method for making an integrated circuit package in accordance with one embodiment of the invention;

FIGS. 4 through 8 illustrate in cross section one example of a method for making an integrated circuit package in accordance with one embodiment of the invention;

FIG. 9 is a flow chart illustrating a method for making an integrated circuit package in accordance with one embodiment of the invention; and

FIG. 10 illustrates an integrated circuit package employing a surface mount component directly to electrical contact pad surfaces in accordance with one embodiment of the invention.

### DETAILED DESCRIPTION OF THE PREFERRED EMBODIMENT

Briefly, an integrated circuit packaging method includes applying an under bump metalization (UBM) layer over an electrical contact pad surface, and any intervening layers, of an integrated circuit die, and applying, such as by soldering, a surface mount component directly to the integrated circuit die by applying the surface mount component to the UBM layer. This provides a direct electrical and mechanical coupling of the surface mount component to the integrated circuit die since the surface mount component is directly electrically connected with the electrical contact pad of the integrated circuit die. As such, impedance may be reduced and the coefficient of thermal mismatch between silicon integrated dies and the surface mount component may be minimized.

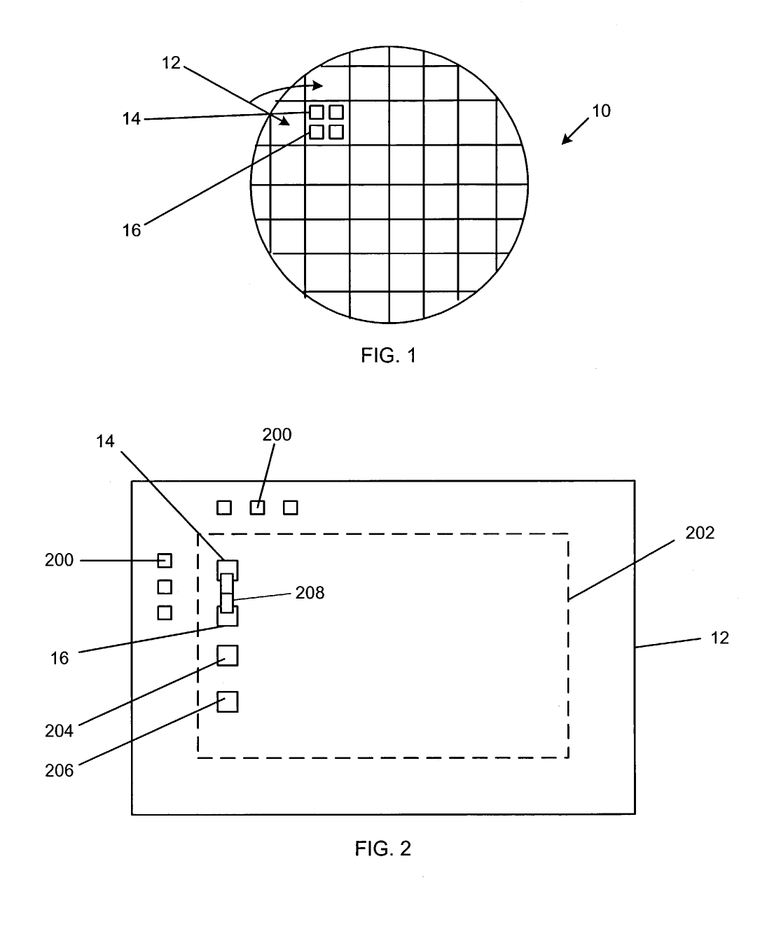

FIG. 1 illustrates a wafer 10 that includes a plurality of integrated circuit dies 12 thereon. Each of the plurality of integrated circuit dies 12 includes a plurality of electrical contact pad surfaces 14 and 16. These electrical contact pad surfaces 14 and 16 are typically different from the wire bonding pad surfaces that are used to wire bond the integrated circuit die to a substrate once the integrated circuit die has been separated from the wafer 10.

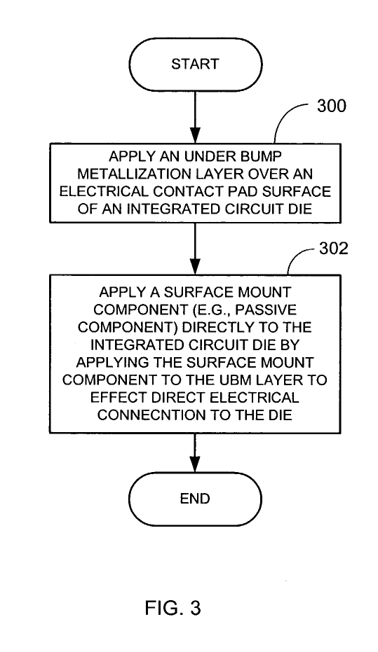

As shown in FIG. 2, wire bonding pads 200 may be set forth around the periphery of the integrated circuit die 12 identified by wire pad region boundary 202. The electrical contact pads 14, 16, 204 and 206 can be suitably separated from the bond pad 200 by a suitable distance such as 1 millimeter or other suitable distance. In this embodiment, the electrical contact pads 14, 16, 204 and 206 are electrically connected to a power and ground grid of the integrated circuit die 12. A surface mount component 208 is shown soldered to the electrical contact pad surfaces 14 and 16 of the integrated circuit die 12 in accordance with the invention.

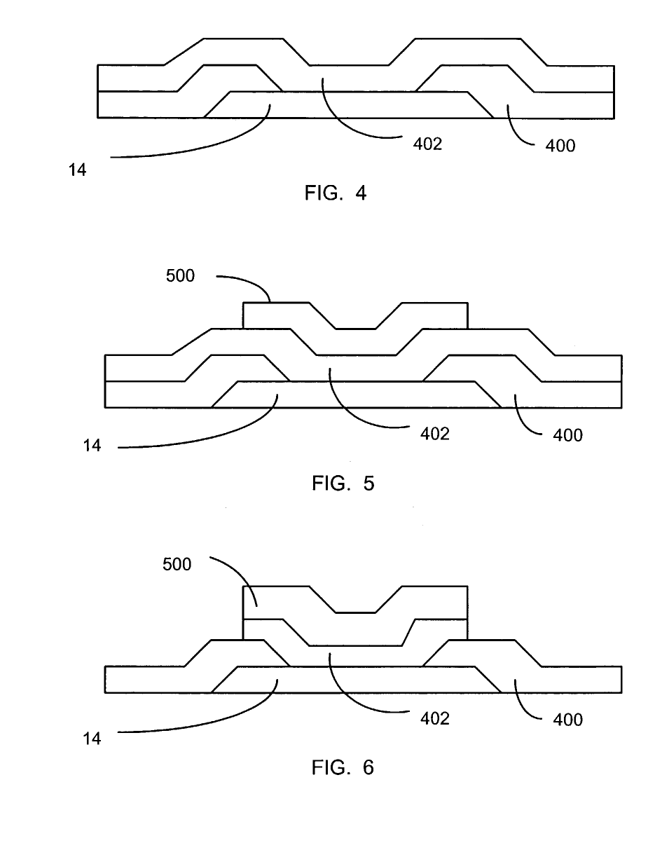

FIG. 3 is a flow chart illustrating one example of a method from making an integrated circuit package that employs the integrated circuit die 12. As shown in block 300, the method includes applying an under bump metalization layer over the electrical contact pad surfaces 14 and 16. As shown in block 302, the method includes applying the surface mount component 208 directly to the integrated circuit die 12 by applying the surface mount component 208 to a UBM layer to effect direct electrical connection to the die 12. By applying the surface mount component to the UBM layer, a direct electrical coupling of the surface mount component 208 to the integrated circuit die 12 is provided through the electrical contact pads 14 and 16. As such, no wire bonding operation is necessary and a shorter distance is provided between the electrical contact pad and the passive surface mount component.

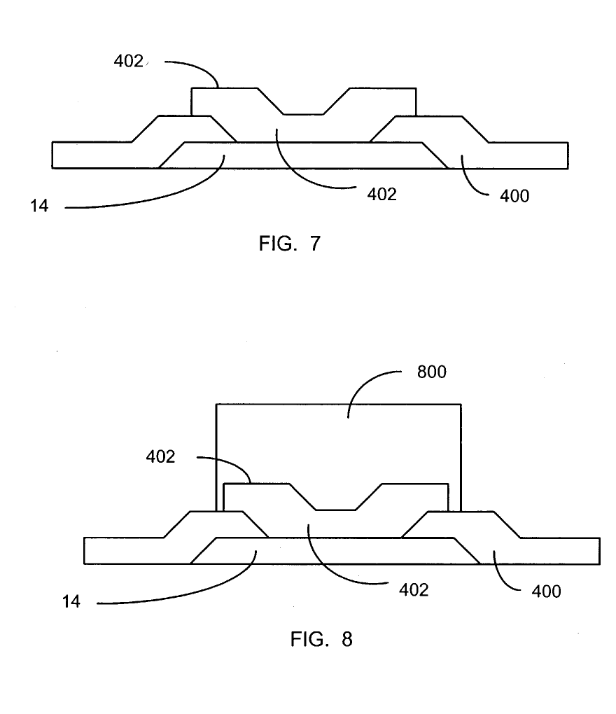

Referring to FIGS. 4 through 9, a method for making an integrated circuit will be described. FIGS. 4 through 8 show for example a cross-sectional view taken from the perspective of an electrical contact pad 14 or 16. The electrical contact pads may be, for example, aluminum pads, copper pads, or any other suitable material or combinations of elements. For purposes of illustration and example only, pads the electrical contact pads 14 and 16 will be described as being aluminum.

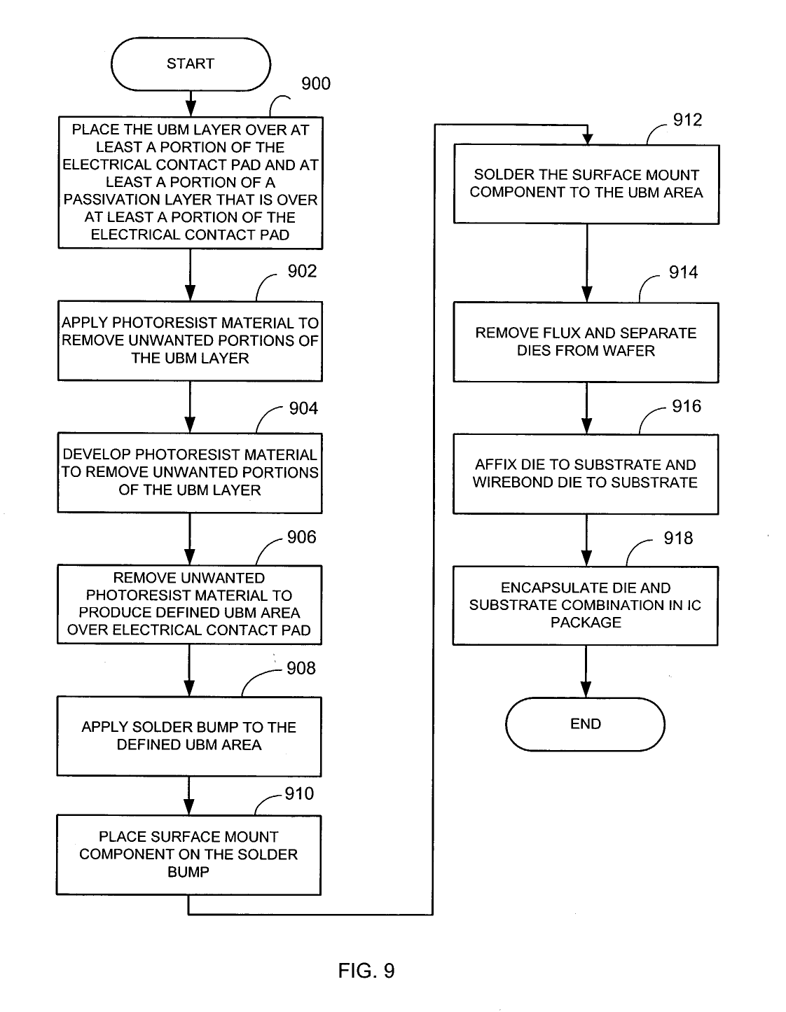

As shown in FIG. 4, a passivation layer 400 is formed over at least a portion of the electrical contact pad 14. The passivation layer may be a nitride, silicon nitride, or polymide or a combination thereof or any other suitable passivation layer as known in the art. As shown in block 900 (FIG. 9) the method includes placing a UBM layer 402 over at least a portion of the electrical contact pad and over at least a portion of the passivation layer 400 that is over at least a portion of the electrical contact pad 14. The UBM layer 402 may be for example an AL/NiV/CU material. Where the electrical contact pad 14 is a copper pad, the UBM layer 402 may be made of for example a TI/NiV/CU material as known in the art.

As shown in block 902 and is illustrated for example in FIG. 5, the method includes applying a layer of photoresist material 500 to remove unwanted portions of the UBM layer 402. The photoresist material 500 may be applied by applying a suitable photoresist layer as known in the art. The UBM layer 402 may be applied using a sputtering process or any other suitable process known in the art. As shown in block 904, and as illustrated in FIG. 6, the method includes developing the photoresist material to remove unwanted portions of the UBM layer 402.

As shown in block 906 and as illustrated in FIG. 7, the method includes removing the unwanted photoresist material to produce a defined UBM area 700 over the electrical contact pad 14. As such, a photoresist pattern is applied to the UBM layer 402 and portions thereof are then removed to produce the defined UBM area 700. As shown in this example, the UBM layer 402 is shown to cover the contact pad and at least a portion of the passivation layer 400.

As shown in FIG. 8, a solder bump 800 such as a rectangular or square solder bump is screened over the UBM layer 402 and over the defined UBM area 700. This is shown in block 908. This may be done using a screening process, plating process or any other suitable process. As such, a solder bump is applied via for example a solder paste printing operation over the defined UBM area 700 on top of the electrical contact pad.

The placing of the surface mount component is then performed using a suitable surface mount component placement machine or other operation as shown in block 910. As shown in block 912, the method may further include soldering the surface mount component to the defined UBM area 700 while for example all of the dies are still in wafer form, by running the wafer through a solder reflow process. Alternatively if desired, the process may include waiting to place the surface mount component on the solder bump after the dies are separated from the wafer. The dies may be epoxied to a substrate and subsequently the surface mount component may be placed on the solder bump and subsequently passed through a solder reflow process.

In any event, if the solder operation produces flux, as shown in block 914, the method includes removing the flux and the embodiment where the dies are still maintained as a wafer, the method includes separating the dies from the wafer by suitably cutting the dies from the wafer or using any other suitable method.

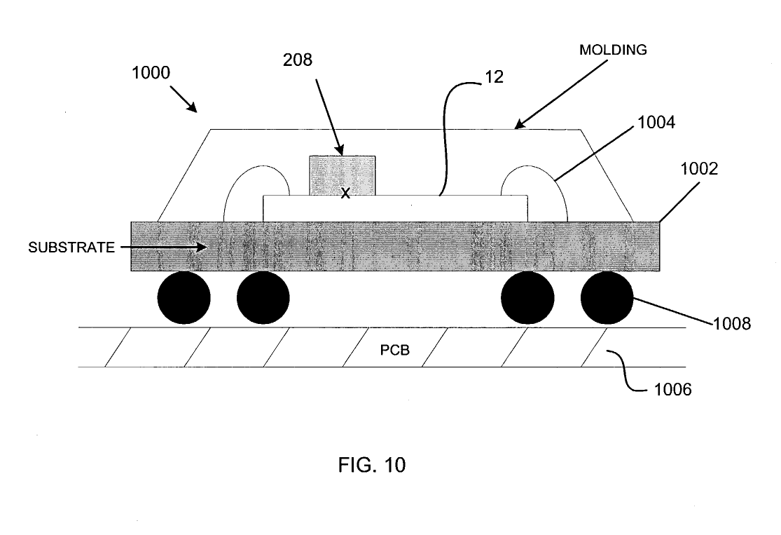

Looking also to FIG. 10, which shows an integrated circuit package 1000 that employs a chip carrier or substrate 1002 such as a printed circuit board or other suitable material and as also shown on block 916, the method includes affixing the integrated circuit die 12 to the substrate 1002 and wire bonding the integrated circuit die to the substrate 1002 via wire bonds 1004. It is known in the art that the integrated circuit die may be epoxied or otherwise affixed to the substrate and any suitable wire bonding process may then be used. Where the integrated circuit package 1000 is to be affixed to a larger printed circuit board 1006, solder balls 1008 or any other suitable attachment mechanism may be used to affix the integrated circuit package 1000 to the printed circuit board 1006. As shown in block 918, prior to affixing the integrated circuit package 1000 to the printed circuit board 1006, the integrated circuit die 12 may be encapsulated using a suitable epoxy or other material. It should be noted that as known in the art, the epoxy that may be used to attach the integrated circuit die to the substrate 102 should preferably have a curing temperature cycle below the reflow temperature of the solder used to attach the surface mount component to avoid reflowing of the solder if desired.

As an alternative embodiment, the mounting of the surface mount component may be done after the dies have been separated from the wafers and after the integrated circuit die has been attached to the substrate 102 and after the wire bonding of the integrated circuit die has been completed. As such, no flux cleaning may be necessary in this process.

The surface mount component may be a passive surface mount component and may include a capacitor, resistor, inductor, or any other suitable passive component. In this embodiment the surface mount component is a capacitor and the electrical contact pads 14 and 16 are coupled to a power and ground connection so that the surface mount capacitor serves as a filtering capacitor.

As such, the above methods and integrated circuit package employs a direct mounting of a passive surface mount device directly to an integrated circuit die using a UBM layering process to, among other things, improve the impedance problems typically associated with wiring bonding of such surface mount components and provide a suitable coefficient of thermal matching between the silicon of the integrated circuit die and the mounted surface mount component. Other advantages will be recognized by those of ordinary skill in the art.

The above detailed description of the invention and the examples described therein have been presented for the purposes of illustration and description. It is therefore contemplated that the present invention cover any and all modifications, variations or equivalents that fall within the spirit and scope of the basic underlying principles disclosed above and claimed herein.

1. A method for making an integrated circuit package comprising:
applying an under bump metallization layer over an electrical contact pad surface of an integrated circuit die wherein applying the under bump metallization layer over the electrical contact pad surface includes the steps of:
placing the under bump metallization layer over at least a portion of the electrical contact pad and at least a portion of a passivation layer that is over at least a portion of the electrical contact pad;
applying a photoresist material over at least a portion of the under bump metallization layer;
developing the photoresist material to remove unwanted portions of the under bump metallization layer;
removing unwanted photoresist material thereby producing a defined under bump metallization area over the electrical contact pad;
applying a solder bump to the defined under bump metallization area;
placing the surface mount component on the solder bump; and
soldering the surface mount component to the under bump metallization area by using a screening process; and
applying a surface mount component directly to the integrated circuit die by applying the surface mount component to the under bump metallization layer thereby effecting a direct electrical coupling of the surface mount component to the integrated circuit die.

2. (Canceled)

3. The method of claim 1 wherein the surface mount component is at least one of: a capacitor, resistor and an inductor.

4. The method of claim 1 wherein applying the solder bump includes applying a solder square to the defined under bump metallization area.

5. A method for making an integrated circuit package comprising:
obtaining a wafer that contains a plurality of integrated circuit dies each having a plurality of electrical contact pad surfaces thereon;
applying an under bump metallization layer over the plurality of electrical contact pad surfaces on the plurality of integrated circuit dies formed in the wafer wherein applying the under bump metallization layer over the electrical contact pad surface includes the steps of:
placing the under bump metallization layer over at least a portion of the electrical contact pad and at least a portion of a passivation layer that is over at least a portion of the electrical contact pad;
applying a photoresist material over at least a portion of the under bump metallization layer;
developing the photoresist material to remove unwanted portions of the under bump metallization layer;
removing unwanted photoresist material thereby producing a defined under bump metallization area over the electrical contact pad;
applying a solder bump to the defined under bump metallization area using a screening process;
placing the surface mount component on the solder bump;
soldering the surface mount component to the under bump metallization area;
applying a surface mount component directly to each of a plurality of the integrated circuit die by applying the surface mount component to the under bump metallization layer thereby effecting a direct electrical coupling of the surface mount component to the integrated circuit die;
separating each of the plurality of integrated circuit dies from the wafer;
affixing at least one of the separated integrated circuit dies to a substrate material; and
wirebonding the separated integrated circuit die to the substrate material.

6. (Canceled)

7. The method of claim 5 wherein the surface mount component is at least one of: a capacitor, resistor and an inductor.

8. The method of claim 5 wherein applying the solder bump includes applying a solder square to the defined under bump metallization area.

9. An integrated circuit package made by the process of at least:
applying an under bump metallization layer over an electrical contact pad surface of an integrated circuit die wherein applying the under bump metallization layer over the electrical contact pad surface includes the steps of:
placing the under bump metallization layer over at least a portion of the electrical contact pad and at least a portion of a passivation layer that is over at least a portion of the electrical contact pad;
applying a photoresist material over at least a portion of the under bump metallization layer;
developing the photoresist material to remove unwanted portions of the under bump metallization layer;
removing unwanted photoresist material thereby producing a defined under bump metallization area over the electrical contact pad;
applying a solder bump to the defined under bump metallization area using a screening process;
placing the surface mount component on the solder bump; and
soldering the surface mount component to the under bump metallization area; and
applying a surface mount component directly to the integrated circuit die by applying the surface mount component to the under bump metallization layer thereby effecting a direct electrical coupling of the surface mount component to the integrated circuit die.

10. (Canceled)

11. The integrated circuit of claim 9 wherein applying the solder bump includes applying a solder square to the defined under bump metallization area.
